(19) United States
(12) Patent Application Publication
(10) Pub. No.: US 2024/0039228 A1
(43) Pub. Date: Feb. 1, 2024

(54) REDUCING ENERGY CONSUMPTION OF A GAS DISCHARGE CHAMBER BLOWER

(71) Applicant: Cymer, LLC, San Diego, CA (US)

(72) Inventors: Mohammad Taghi Mohebbi, San Diego, CA (US); Matthew Minakais, San Diego, CA (US); Spencer Ryan Williams, San Diego, CA (US)

(21) Appl. No.: 18/256,290

(22) PCT Filed: Dec. 9, 2021
(86) PCT No.: PCT/US2021/062705

§ 371 Date: Jun. 7, 2023

Related U.S. Application Data
(60) Provisional application No. 63/129,122, filed on Dec. 22, 2020.

(51) Int. Cl. H01S 3/036; H01S 3/225; H01S 3/104

(52) U.S. Cl. CPC H01S 3/036; H01S 3/225; H01S 3/104

(57) ABSTRACT

In some general aspects, an apparatus for a light source includes: a monitoring module configured to monitor a fault status of one or more operating conditions of the light source; a decrement module configured to reduce an operating speed of a blower arranged in a gas discharge chamber of the light source if the fault status relating to one or more operating conditions of the light source is clear and if the decreased operating speed would be at or above a baseline speed; and an increment module configured to increase the operating speed of the blower if the fault status relating to one or more operating conditions of the light source is flagged. The blower is configured to displace a gas mixture including a gain medium from an energy source within the gas discharge chamber, the energy source configured to supply energy to the gas mixture.

### CROSS REFERENCE TO RELATED APPLICATIONS

This application claims priority to U.S. Application No. 63/129,122 filed Dec. 22, 2020, titled REDUCING ENERGY CONSUMPTION OF A GAS DISCHARGE CHAMBER BLOWER, which is incorporated herein in its entirety by reference.

### TECHNICAL FIELD

The disclosed subject matter relates to controlling a blower arranged in a gas discharge chamber of a light source to thereby reduce energy consumed by the blower during operation of the light source.

### BACKGROUND

One kind of gas discharge light source used in photolithography is termed an excimer light source or laser. Typically, an excimer laser uses a combination of one or more noble gases, which can include argon, krypton, or xenon, and a reactive gas, which can include fluorine or chlorine. The excimer laser can create an excimer, a pseudo-molecule, under appropriate conditions of electrical simulation (energy supplied) and high pressure (of the gas mixture), the excimer only existing in an energized state. The excimer in an energized state gives rise to amplified light in the ultraviolet range. An excimer light source can use a single gas discharge chamber or a plurality of gas discharge chambers. When the excimer light source is performing, the excimer light source produces a deep ultraviolet (DUV) light beam. DUV light can include wavelengths from, for example, about 100 nanometers (nm) to about 400 nm.

The DUV light beam can be directed to a photolithography exposure apparatus or scanner, which is a machine that applies a desired pattern onto a target portion of a substrate (such as a silicon wafer). The DUV light beam interacts with a projection optical system, which projects the DUV light beam through a mask onto the photoresist of the wafer. In this way, one or more layers of chip design is patterned onto the photoresist and the wafer is subsequently etched and cleaned.

### SUMMARY

In some general aspects, an apparatus for a light source includes: a monitoring module configured to monitor a fault status of one or more operating conditions of the light source; a decrement module configured to reduce an operating speed of a blower arranged in a gas discharge chamber of the light source if the fault status relating to one or more operating conditions of the light source is clear and if the decreased operating speed would be at or above a baseline speed; and an increment module configured to increase the operating speed of the blower if the fault status relating to one or more operating conditions of the light source is flagged. The blower is configured to displace a gas mixture including a gain medium from an energy source within the gas discharge chamber, the energy source configured to supply energy to the gas mixture.

Implementations can include one or more of the following features. For example, the baseline speed of the blower can be related to an age of the gas discharge chamber, the baseline speed changing as the gas discharge chamber ages over time.

Each of the one or more operating conditions can be defined by a performance metric relating to the light source or to a light beam produced by the light source. The one or more performance metrics can include a wavelength histogram associated with the light beam, an energy dose error associated with the light beam, an energy error associated with the light beam, and an operating point of the gas discharge chamber within the light source. The fault status can be flagged if at least one of the associated performance metrics is not within a threshold range of that performance metric, and the fault status can be clear if all of the associated performance metrics are within their respective threshold range. At least one of the operating conditions of the light source can be proactive such that the operating speed of the blower is adjusted prior to the value of the associated performance metric not being within the threshold range of the performance metric. At least one of the operating conditions can be reactive such that the operating speed of the blower is adjusted after the value of the associated performance metric is not within the threshold range of the performance metric. Each proactive operating condition can be associated with a limited threshold range that is tighter than the actual threshold range of the performance metric, and the operating speed of the blower can be adjusted prior to the value of the associated performance metric not being within the actual threshold range by determining the fault status of the proactive operating condition based on the limited threshold range.

The fault status relating to the one or more operating conditions of the light source can be determined using a low pass filter or a weighted sum filter.

The decrement module can be configured to reduce the operating speed of the blower by a decrement speed step size, and the increment module can be configured to increase the operating speed of the blower by an increment speed step size. The increment speed step size can be larger than the decrement speed step size. The increment speed step size can be less than or equal to 25 rotations per minute (rpm), and the decrement speed step size can be about one half, one third, one fourth, or one fifth of the increment speed step size.

The operating speed of the blower can be adjusted by the increment and decrement modules within a blower speed range defined by a minimum blower speed and a maximum blower speed.

The decrement module and the increment module can each be configured to avoid blower operating speeds at which the aliased frequency of the second harmonic of the blower interferes with a spectral feature control system associated with the light source. The interfering blower operating speeds can be dependent on a repetition rate at which the light source produces light beams.

The apparatus can also include a baseline module configured to increase the operating speed of the blower if the operating speed of the blower is below the baseline speed.

The apparatus can be a state machine for the light source such that the monitoring module can be a monitoring state, the decrement module can be a decrement state, and the increment module can be an increment state. After decreasing the operating speed of the blower in the decrement state, the state machine can transition from the decrement state to the increment state if the fault status relating to one or more operating conditions of the light source is flagged. The state machine can include a baseline state configured to increase the operating speed of the blower if the operating speed of the blower is below the baseline speed, and the state machine can transition from the decrement state to the baseline state if the operating speed of the blower crosses below the baseline speed. After the baseline state increases the operating speed of the blower in the baseline state, the state machine can transition from the baseline state to the increment state if the fault status relating to one or more operating conditions of the light source is flagged. The state machine can transition from the monitoring state to the baseline state if the operating speed of the blower is below the baseline speed. After increasing the operating speed of the blower in the increment state, the state machine can transition from the increment state to the monitoring state if the increased operating speed of the blower is greater than a target speed. The state machine can transition from the monitoring state to the increment state if the fault status relating to one or more operating conditions of the light source is flagged. The state machine can transition from the monitoring state to the decrement state if one or more exit criteria are met, the exit criteria being based on one or more of the baseline speed, a number of light beam pulses produced by the light source, and events that lead to an improvement in performance of the light source.

In other general aspects, a blower controller for a light source includes a control system in communication with a blower arranged in a gas discharge chamber of the light source, the blower configured to displace a gas mixture including a gain medium from an energy source within the gas discharge chamber, the energy source configured to supply energy to the gas mixture. The control system is configured to: monitor a fault status of one or more operating conditions of the light source; decrease an operating speed of the blower in a decrement state if the fault status relating to one or more operating conditions of the light source is clear and if the decreased operating speed would be at or above a baseline speed; and increase the operating speed of the blower in an increment state if the fault status relating to one or more operating conditions of the light source is flagged.

Implementations can include one or more of the following features. For example, the control system can include: a computer-readable memory module; and one or more electronic processors coupled to the computer-readable memory module.

The fault status relating to the one or more operating conditions can be defined using binary notation, such that the fault status is assigned a value of zero if the fault status is clear and a value of one if the fault status is flagged.

The control system can be configured to increase the operating speed of the blower in the increment state if the decreased operating speed of the blower is below the baseline speed.

In other general aspects, a method is performed for controlling a blower arranged in a gas discharge chamber of a light source. The method includes: monitoring a fault status of one or more operating conditions of the light source; decrementing an operating speed of the blower if the fault status relating to one or more operating conditions of the light source is clear and if the decreased operating speed would be at or above a baseline speed; and incrementing the operating speed of the blower if the fault status relating to one or more operating conditions of the light source is flagged.

Implementations can include one or more of the following features. For example, the operating speed of the blower can be decremented by reducing an amount of vibrations within the light source caused by movement of the blower. The operating speed of the blower can be decremented by reducing the operating speed of the blower by a decrement speed step size, and the operating speed of the blower can be incremented by increasing the operating speed of the blower by an increment speed step size. The method can further include determining the increment and decrement speed step sizes of the blower, each speed step size dependent on the fault status relating to the one or more operating conditions of the light source.

The operating speed of the blower can be decremented and incremented by adjusting the operating speed of the blower within a blower speed range defined by a minimum blower speed and a maximum blower speed. The method can also include determining the blower speed range of the blower, the blower speed range dependent on the fault status of the one or more operating conditions of the light source.

The method can further include incrementing the operating speed of the blower if the decreased operating speed of the blower is below the baseline speed.

The fault status relating to the one or more operating conditions can be monitored by monitoring one or more exit criteria such that the operating speed of the blower is decreased only if one or more of the exit criteria are met. The exit criteria can be based on the baseline speed and a number of light beam pulses produced by the light source, the exit criteria being met if the operating speed of the blower is greater than the baseline speed and the number of light beam pulses is greater than a minimum number of pulses.

In other general aspects, an ultraviolet light source includes: a light generation apparatus comprising one or more gas discharge chambers configured to hold a gas mixture including a gain medium, to house an energy source configured to supply energy to the gas mixture, and to produce a light beam, at least one of the gas discharge chambers being configured to hold a blower configured to displace the gas mixture from the energy source within the gas discharge chamber; and an apparatus configured to adjust an operating speed of the blower. The apparatus includes: a monitoring module configured to monitor a fault status relating to one or more operating conditions of the light source; a decrement module configured to decrease the operating speed of the blower if the fault status relating to one or more operating conditions of the light source is clear and if the decreased operating speed would be at or above a baseline speed; and an increment module configured to increase the operating speed of the blower if the fault status of one or more operating conditions of the light source is flagged.

Implementations can include one or more of the following features. For example, the gain medium can be configured to emit deep ultraviolet (DUV) light in response to a voltage signal being applied to the energy source. The gaseous gain medium can include argon fluoride (ArF), krypton fluoride (KrF), or xenon chloride (XeCl). The light generation apparatus can include two gas discharge chambers including a master oscillator configured to produce a seed light beam and a power amplifier configured to produce an output light beam from the seed light beam. The light generation apparatus can include a plurality of gas discharge chambers, and each of the gas discharge chambers can be configured to emit a light beam toward a beam combiner.

The apparatus can include a baseline module configured to increase the operating speed of the blower if the decreased operating speed of the blower is below the baseline speed.

### DESCRIPTION OF DRAWINGS

FIG. 1 is a block diagram of an ultraviolet light source that produces a light beam for use by a lithography exposure apparatus, the light source including a light generation apparatus having one or more gas discharge chambers, each including a blower, and an apparatus at least partly configured to control a speed of the blower;

FIG. 2 is a block diagram of an implementation of the apparatus of FIG. 1 including a monitoring module, a decrement module, and an increment module, and optionally a baseline module;

FIG. 3 is a schematic illustration showing how an overall fault status of the light source is determined for use by the apparatus of FIGS. 1 and 2 based on one or more operating conditions of the light source;

FIGS. 4A-4C are exemplary graphs showing how a baseline speed changes relative to an age of the discharge chamber for different discharge chambers;

FIG. 5 is a diagram of a state machine representing an implementation of the apparatus, the state machine including a monitoring state (performed by the monitoring module), a decrement state (performed by the decrement module), and an increment state (performed by the increment module);

FIG. 6A is a flow chart of a procedure performed by the decrement module while the state machine is in the decrement state;

FIG. 6B is a flow chart of a procedure performed by the monitoring module while the state machine is in the monitoring state;

FIG. 6C is a flow chart of a procedure performed by the baseline module while the state machine is in a baseline state;

FIG. 6D is a flow chart of a procedure performed by the increment module while the state machine is in the increment state;

FIG. 7A is a flow chart of a procedure performed by the apparatus for controlling the speed of the blower of the light source of FIGS. 1 and 2;

FIG. 7B is an additional step that can be included in the procedure of FIG. 7A;

FIG. 8 is a block diagram of an implementation of a light source in which the light generation apparatus includes two gas discharge chambers in a master oscillator-power amplifier arrangement;

FIG. 9A is a block diagram of an implementation of a light source in which the light generation apparatus includes a plurality of gas discharge chambers and an implementation of the lithography exposure apparatus; and

FIG. 9B is a block diagram of an implementation of a projection optical system of the lithography exposure apparatus of FIG. 9A.

### DESCRIPTION

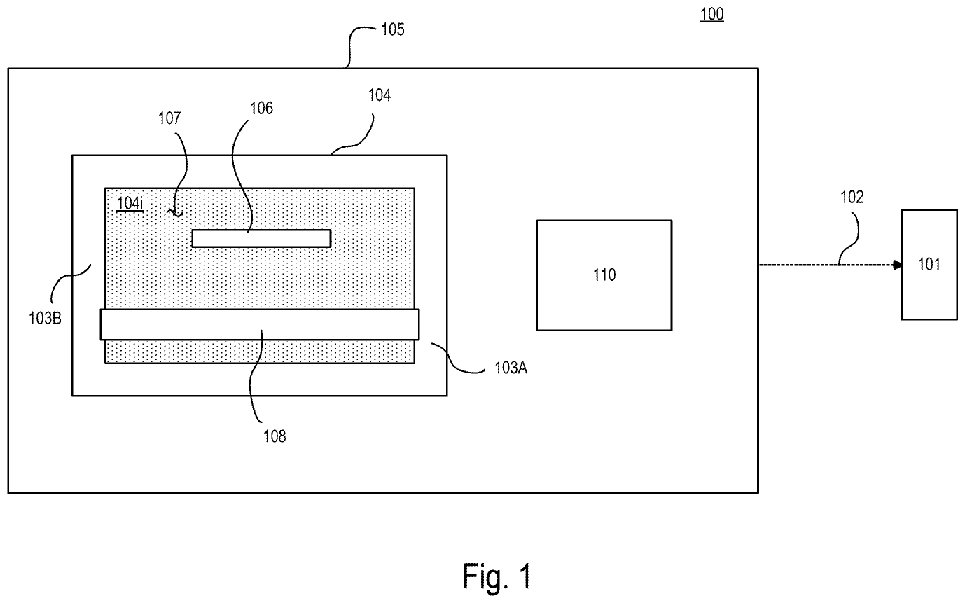

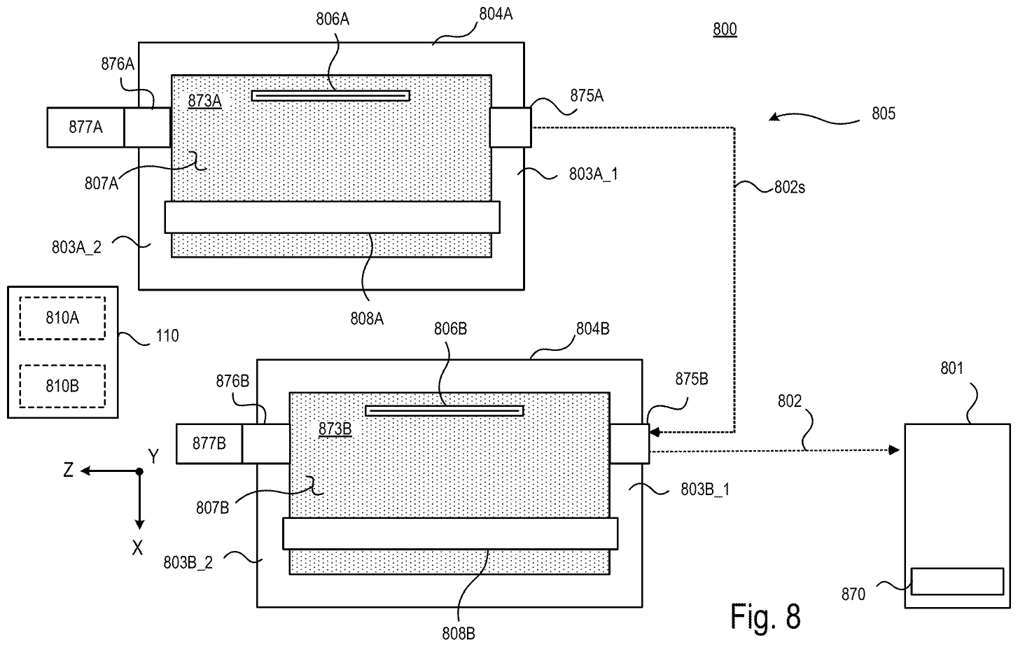

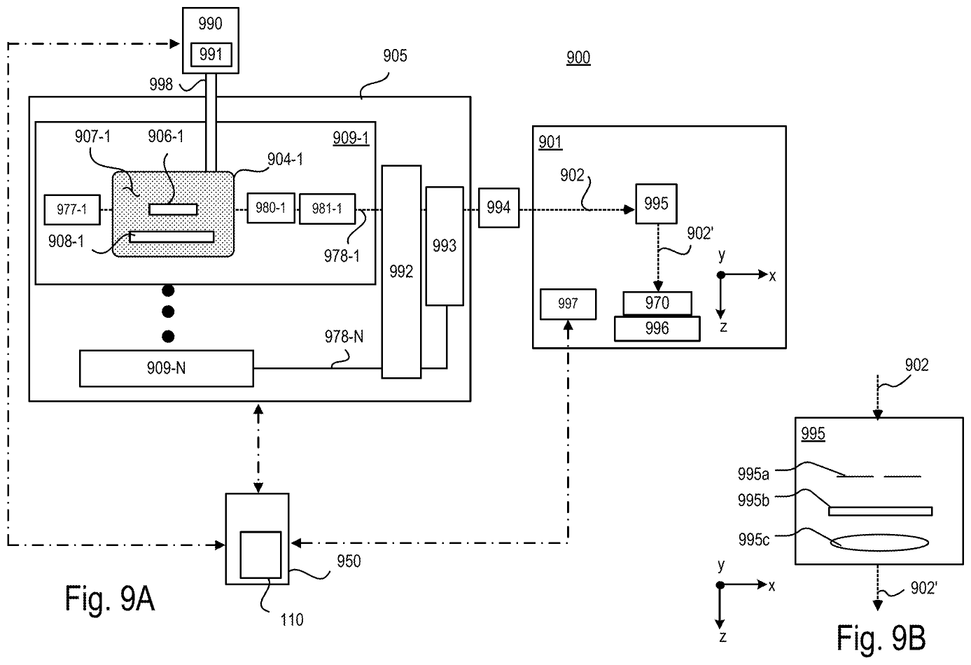

Referring to FIG. 1, an ultraviolet light source 100 includes a light generation apparatus 105 including one or more gas discharge chambers 104, and an apparatus 110. In the example of FIG. 1, the light generation apparatus 105 includes one discharge chamber 104, but it can include a plurality of discharge chambers 104 (such as shown in FIGS. 8 and 9A). The gas discharge chamber 104 is configured to hold a gas mixture 107 including a gain medium within an interior cavity 104i of the gas discharge chamber 104, house an energy source 106 configured to supply energy to the gas mixture 107 to thereby produce a light beam 102. The gain medium of the gas mixture 107 is configured to emit deep ultraviolet (DUV) light in response to a voltage signal being applied to the energy source 106. The energy source 106 can be configured to supply the energy to the gas mixture 107 in short (for example, nanosecond) current pulses using a high-voltage electric discharge interspersed by periods of no energy. The gas mixture 107 produces a pulse of the light beam 102 from a population inversion occurring in the gain medium of the gas mixture 107 by way of stimulated emission when energy from the energy source 106 is provided to the gas mixture 107. As such, the light beam 102 is a pulsed light beam that includes pulses of light that are centered around a wavelength in the DUV range, for example, with wavelengths of 248 nanometers (nm) or 193 nm. For a DUV light source, the gaseous gain medium of the gas mixture 107 can include, for example, argon fluoride (ArF), krypton fluoride (KrF), or xenon chloride (XeCl). The light beam 102 is directed along a path toward a lithography exposure apparatus 101. The light beam 102 is used to pattern microelectronic features on a substrate or wafer received in the lithography exposure apparatus 101. The size of the microelectronic features patterned on the wafer depends on the wavelength of the pulsed light beam 102, with a lower wavelength resulting in a small minimum feature size or critical dimension. For example, when the wavelength of the pulsed light beam 102 is 248 nm or 193 nm, the minimum size of the microelectronic features can be, for example, 50 nm or less.

Specifically, the energy source 106 can include a cathode and an anode, and a potential difference between the cathode and the anode forms an electric field in the gas mixture 107. The electric field provides energy to the gain medium within the gas mixture 107, such energy sufficient to cause a population inversion and to enable generation of a pulse of light via stimulated emission. Repeated creation of such a potential difference forms the train of pulses of light that eventually make up the light beam 102. A “discharge event” is the application of voltage that forms a potential difference sufficient to cause an electrical discharge in the gain medium of the gas mixture 107 and the emission of a pulse of light.

When an optical pulse is generated from the gas mixture 107 near the energy source 106, there is a period of time during which the molecules within the gas mixture 107 recover. This recovery time is longer than the time between pulses of the energy source 106. Moreover, if another pulse of energy is supplied to the recovering gas mixture 107, which remains nearest the energy source 106, then output quality of the resultant optical pulse of the light beam 102 will be reduced and can lead to failure in the light generation apparatus 105. To fix this issue, the gas discharge chamber 104 holds a blower 108, which is fixed to walls 103A, 103B of the gas discharge chamber 104. In various implementations, the blower 108 can include a rotating structure such as a fan. See, for example, U.S. Pat. No. 6,765,946, issued on Jul. 20, 2004 and naming Partlo, et. al. as inventors, which is incorporated herein by reference in its entirety. The blower 108 is configured to regularly displace the portion of the recovering gas mixture 107 away from the energy source 106 within the gas discharge chamber 104 to enable fresh gas mixture 107 to interact with the energy source 106 before a next pulse of the energy source 106 is produced. If the speed of the blower 108 is too low, then arcing, dropouts, and inefficiency can occur in the gas discharge chamber 104, and the gas discharge chamber 104 can fail when the blower 108 is unable to sufficiently clear the portion of the recovering gas mixture 107. Another consideration is that the rotation or motion of the blower 108 can cause vibrations within the gas discharge chamber 104 that can impact one or more spectral properties of the light beam 102 as well as the dose performance of the light beam 102 at the lithography exposure apparatus 101.

During operation of the light source 100, an operating speed of the blower 108 (that is the speed or rate at which the blower 108 rotates about a rotation axis of the blower 108) can be maintained constant at a pre-configured speed. Specifically, the operating speed of the blower 108 can be maintained at a maximum blower speed such that the operating speed 108 of the blower does not change over time and as the light source 100 operates. Under such conditions, the blower 108 can consume a roughly constant amount of energy over time, or, in other words, requires a constant power as the light source 100 operates, which can be expensive and cost inefficient at the least. Accordingly, as discussed herein, the operating speed of the blower 108 is changed or adjusted by the apparatus 110 over time (as the light source 100 operates) based on a fault status of one or more operating conditions of the light source 100 and a baseline speed of the blower 108 (which is the minimum allowed speed of the blower 108). In this way, the apparatus 110 acts as a blower controller that controls the operating speed of the blower 108 by adjusting the operating speed between a minimum blower speed and a maximum blower speed that together define a safe blower speed range of the blower 108 during operation of the light source 100. In other words, as the light source 100 operates, the apparatus 110 adjusts the operating speed of the blower 108 within a safe blower speed range within which failures and/or problems do not occur within the light source 100, and also adjusts the operating speed of the blower 108 such that more energy is conserved by the blower 108 and, thus, less energy is consumed by the light source 100. Details of the apparatus 110 are provided next.

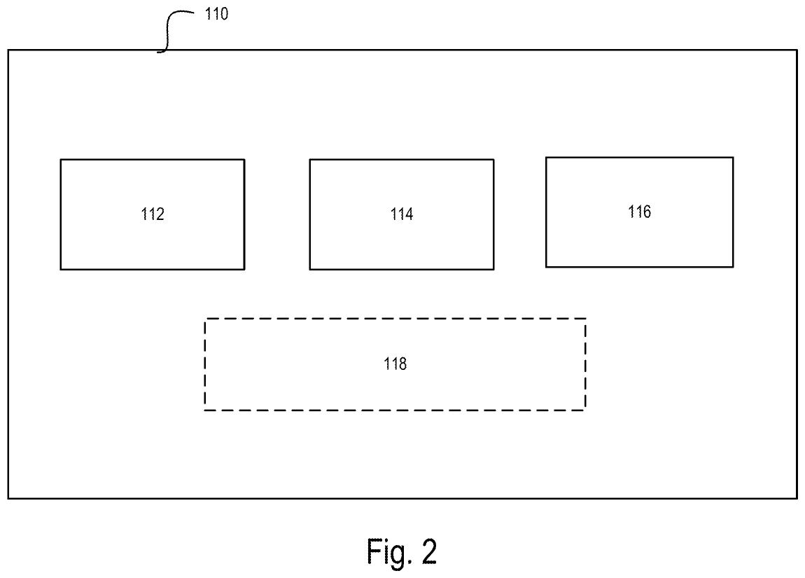

Referring to FIG. 2, the apparatus 110 (or blower controller) includes a monitoring module 112, a decrement module 114, and an increment module 116.

In general, the monitoring module 112 is configured to monitor a fault status relating to one or more operating conditions of the light source 100. For example, each of the one or more operating conditions can be defined by a performance metric relating to the light source 100 or to the light beam 102 produced by the light source 100. The fault status can be considered to be flagged if at least one of the associated performance metrics is not within a threshold range of that performance metric, and the fault status can be considered to be clear if all of the associated performance metrics are within their respective threshold range. Thus, as the light source 100 operates, the monitoring module 112 can monitor the one or more operating conditions of the light source 100 by monitoring the one or more associated performance metrics.

In general, the decrement module 114 is configured to decrease the operating speed of the blower 108 if the fault status relating to one or more operating conditions of the light source 100 is clear and if the decreased operating speed would be at or above the baseline speed of the blower 108 (which is the minimum allowed speed of the blower 108). For example, the decrement module 114 can be configured to reduce the operating speed of the blower 108 by a decrement speed step size.

In general, the increment module 116 is configured to increase the operating speed of the blower 108 if the fault status of one or more operating conditions of the light source 100 is flagged. The increment module 116 can be configured to increase the operating speed of the blower 108 by an increment speed step size. In one example, the increment step size can be, for example, less than or equal to 25 rotations per minute (rpm). In this example, the increment speed step size is larger than the decrement speed step size, which can be about one half, one third, one fourth, or one fifth of the increment speed step size.

The apparatus 110 can also include a baseline module 118 configured to increase the operating speed of the blower 108 if the operating speed of the blower 108 is below the baseline speed.

As the light source 100 operates, the operating speed of the blower 108 is adjusted by the increment and decrement modules 114, 116, and also the baseline module 118, within a blower speed range defined by a minimum blower speed and a maximum blower speed. The blower speed range is a safe range within which the light source 100 does not have problems and/or failures, and properly operates. In this way, the apparatus 110 controls the operating speed of the blower 108 by adjusting the operating speed within the safe blower speed range such that minimal energy is consumed by the blower 108 and the energy consumed by the light source 100 is reduced.

The modules 112, 114, 116, 118 of the apparatus 110 can be implemented in a control system in communication with the blower 108 to thereby control the blower 108. As such, the control system of the blower controller 108 is configured to monitor the fault status of one or more operating conditions of the light source 100, decrease the operating speed of the blower 108 in a decrement state if the fault status relating to one or more operating conditions of the light source 100 is clear and if the decreased operating speed would be at or above a baseline speed, and increase the operating speed of the blower 108 in an increment state if the fault status relating to one or more operating conditions of the light source 100 is flagged. The control system of the blower controller 110 can also be configured to increase the operating speed of the blower 108 in the increment state if the decreased operating speed of the blower 108 is below the baseline speed.

The apparatus 110 can include, for example, a computer-readable memory module, and one or more electronic processors coupled to the computer-readable memory module. Each of the modules 112, 114, 116, 118 can be in communication with the memory module and can be controlled by the one or more electronic processors. For example, each module 112, 114, 116, 118 can include or have access to one or more programmable processors and can each execute a program of instructions to perform desired functions by operating on input data and generating appropriate output. Each module 112, 114, 116, 118 can be implemented in any of digital electronic circuitry, computer hardware, firmware, or software. In further implementations, each module 112, 114, 116, 118 accesses memory within the memory module, which is also configured to store information output from one or more of the module 112, 114, 116, 118, information from the discharge chamber 104, or information about other aspects of the light generation apparatus 105, such information being available for various use by the modules 112, 114, 116, 118 during operation of the apparatus 110. The memory within the memory module can be read-only memory and/or random-access memory and can provide a storage device suitable for tangibly embodying computer program instructions and data. The apparatus 110 can also include one or more input devices (such as a keyboard, touch-enabled devices, audio input devices) and one or more output devices such as audio output or video output.

In examples in which the apparatus 110 acts as a blower controller, the fault status relating to the one or more operating conditions can be defined (by the control system) using binary notation. Specifically, the fault status can be assigned a value of zero (0) if the fault status is clear and a value of one (1) if the fault status is flagged. Details of the fault status relating to one or more operating conditions of the light source 100 are provided next.

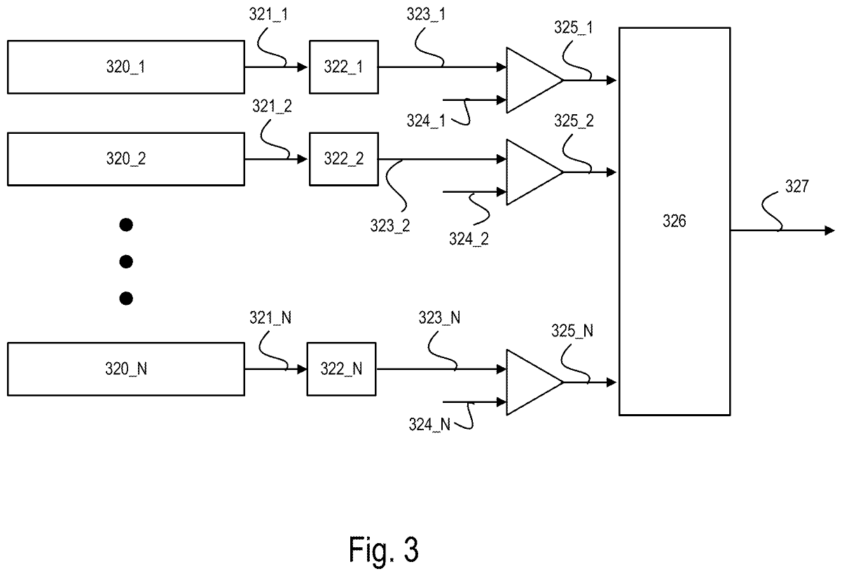

Referring to FIG. 3, an overall fault status 327 of the light source 100 is determined by the apparatus 110 at each iteration based on one or more operating conditions of the light source 100. Each of the one or more operating conditions is defined by a performance metric 320_1 to 320_N relating to the light source 100 or to the light beam 102 produced by the light source 100. The fault status 327 that the apparatus 110 uses to control the blower 108 should be based on system parameters, metrics, and signals that are affected in a significant manner by changes in the speed of the blower 108.

In the example of FIG. 3, the one or more performance metrics 320_1 to 320_N include a spectral feature accuracy associated with the light beam 102, an energy dose error associated with the light beam 102, an energy error associated with the light beam 102, an actuator operating point of the light generation apparatus 105 within the light source 100, and a gas discharge chamber dropout rate.

The spectral feature accuracy represents the stability and accuracy of a spectral feature (such as the wavelength) of the light beam 102 produced by the light source 100. Specifically, the spectral feature accuracy relating to wavelength is based on a mean and a standard deviation of the error of the wavelength of the light beam 102 calculated over a moving window of M pulses of the light beam 102, for M is an integer number equal to or greater than one. The value of the spectral feature accuracy can be measured/calculated directly, or it can be estimated from other measured data.

The energy dose error represents a difference between a desired or target dose at the wafer and an actual dose at the wafer received in the lithography exposure apparatus 107. The dose at the wafer is the amount of optical energy that the light beam 102 delivers per unit area over an exposure time or a particular number of pulses at the wafer. While the energy dose error could be directly measured/calculated, it is alternatively possible to estimate the energy dose error from other measured data.

The energy error represents a standard deviation of the measured energy of the light beam 102. In particular, the energy error can be considered a difference between the amount of energy in the pulse of the light beam 102 and a target energy. While the energy error could be directly measured, it is alternatively possible to estimate the energy error from other data.

The actuator operating point of the light generation apparatus 105 characterizes where, within a range of possible settings, values, or conditions, an actuator within the light generation apparatus 105 is operating. In some implementations, as discussed below with respect to FIG. 8, the actuator can be a timing module that is connected to a first stage including a first discharge chamber 804A (the first stage constituting a master oscillator) and a second stage including a second discharge chamber 804B (the second stage constituting a power amplifier) of a light generation apparatus 805. Such a timing module controls a relative timing between a first trigger signal sent to a first energy source 806A of the first discharge chamber 804A and a second trigger signal sent to the second energy source 806B of the second discharge chamber 804B. This relative timing can be referred to as differential timing. In these implementations, the metric for the actuator operating point of the light generation apparatus 805 can quantify a displacement of the actual relative timing from a peak efficiency differential timing (Tpeak), where Tpeak is the value of the relative timing when the light generation apparatus 805 produces a light beam 802 having a maximum energy at a particular input energy applied to the light generation apparatus 805 (via the energy sources 806A, 806B). This metric for the actuator operating point can be calculated or estimated based on a voltage or energy supplied to the energy sources 806A, 806B; an output energy of the light beam 802, and the differential timing.

The gas discharge chamber dropout rate quantifies the failure mechanism in which the blower 108 is unable to sufficiently clear the portion of the recovering gas mixture 107 and thus, the gas mixture is not moved fast enough through the gas discharge chamber 104, which causes arching and energy loss in the gas discharge chamber 104.

In some implementations, as discussed above, one or more of the performance metrics 320_1 to 320_N relating to the light source 100 can be unavailable at certain moments during operation or within certain systems, and the apparatus 110 can estimate a value of the unavailable performance metrics to determine the fault status 327 based on other available data. To calculate the overall fault status 327, the apparatus 110 receives the performance metrics 3201, 320_2, . . . 320_N.

Each of the one or more performance metrics 320_1 to 320_N is associated with a respective value 321_1 to 321_N that is passed through a respective filter 322_1 to 322_N to remove the effect of noise or temporary performance issues that can occur during operation. For example, each of the filters 322_1 to 322_N can be a low pass filter or a weighted sum filter, such that the fault status 327 relating to the one or more operating conditions 320_1 to 320_N of the light source 100 is determined using the filter 322_1 to 322_N (including the low pass filter or the weighted sum filter). Moreover, each of the filters 322_1 to 322_N can have a configurable transfer function to filter the values 321_1 to 321_N of the performance metrics 320_1 to 320_N.

Filtered values 323_1 to 323_N of the performance metrics 320_1 to 320_N are output from each of the respective filters 322_1 to 322_N. To determine a respective fault status 325_1 to 325_N that is associated with each of the performance metrics 320_1 to 320_N (and, thus, operating conditions), each of the filtered values 323_1 to 323_N are compared to a respective threshold range 324_1 to 324_N that is associated with that respective performance metric 320_1 to 320_N. If it is determined that the respective performance metric 320_1 to 320_N is not within the threshold range 324_1 to 324_N of that performance metric 320_1 to 320_N, then the fault status 325_1 to 325_N of that performance metric 320_1 to 320_N is flagged. If it is determined that the respective performance metric 320_1 to 320_N is within the threshold range 3241 to 324_N of that performance metric 320_1 to 320_N, then the fault status 325_1 to 325_N of that performance metric 320_1 to 320_N is clear. As described above, the fault status 325_1 to 325_N can be assigned a value of zero (0) if the fault status 325_1 to 325_N is clear and a value of one (1) if the fault status 325_1 to 325_N is flagged.

Each fault status 325_1 to 325_N is input to a fault status module 326 (which can be a controller) that determines the overall fault status 327 of the light source 100 based on the fault statuses 325_1 to 325_N of the performance metrics 320_1 to 320_N that relate to the light source 100. For example, in some implementations, if any one of the fault statuses 325_1 to 325_N is flagged (or has a value of 1), then the overall fault status 327 of the light source 100 is flagged (or has a value of 1). And, if all of the fault statuses 325_1 to 325_N are clear (or have a value of 0), then the overall fault status 327 of the light source 100 is clear (or has a value of 0). In this way, the overall fault status 327 of the light source 100 can be determined, and the apparatus 110 can control the blower 108 based on the fault status 327 of the light source 100 to thereby reduce energy consumption by the blower 108 during operation. In other implementations, the fault status module 326 can be configured to flag the overall fault status 325 only if a plurality of the fault statuses 325_1 to 325_N are flagged.

Details of the baseline speed of the blower 108 are provided next.

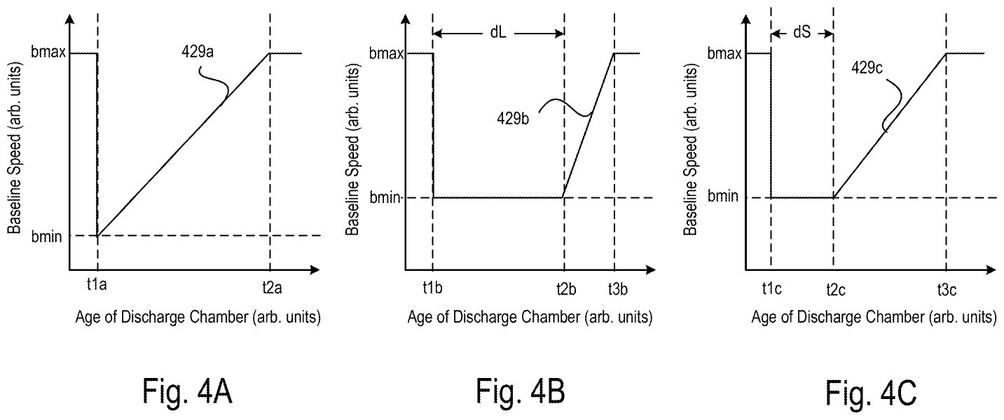

Referring to FIGS. 4A-4C, the baseline speed of the blower 108 can be related to an age of the gas discharge chamber 104. In the examples of FIGS. 4A-4C, the baseline speed changes as the gas discharge chamber 104 ages over time. In other words, the baseline speed changes as the number of pulses of the light beam 102 generated by the gas discharge chamber 104 increases over time (and as the gas discharge chamber 104 ages). In these examples, the apparatus 110 adjusts the baseline operating speed of the blower 108 between a minimum baseline speed bmin and a maximum baseline speed bmax. Any of the modules 114, 116, 118 or another module of the apparatus 110 can perform this adjustment. In general, the baseline speed of the blower 108 is required to be increased as the gas discharge chamber 104 ages and performance failures, problems, and/or errors occur more frequently within the aging light source 100 (and within the gas discharge chamber 104). By increasing the baseline speed of the gas discharge chamber 104 as the discharge chamber 104 ages, the performance failures, problems, and/or errors that can occur within the aging light source 100 are reduced or mitigated.

In the example of FIG. 4A, the apparatus 110 adjusts the baseline speed from the maximum baseline speed bmax to the minimum baseline speed bmin at time t1a. Then, at time t1a, the apparatus 110 begins to gradually increase the baseline speed. The baseline speed of the blower 108 is incremented at a constant rate 429a (or slope) as the gas discharge chamber 104 ages over time (or as pulses of the light beam 102 are generated by the gas discharge chamber 104). The baseline speed of the blower 108 is increased or incremented from the minimum baseline speed bmin to the maximum baseline speed bmax such that the baseline speed reaches the maximum baseline speed bmax at time t2a that is at the end of the lifetime of the gas discharge chamber 104.

In the example of FIG. 4B, the apparatus 110 adjusts the baseline speed from the maximum baseline speed bmax to the minimum baseline speed bmin at time t1b. While the gas discharge chamber 104 remains young in age for an amount of time dL between times t1b and t2b, the baseline speed of the blower 108 is not changed and remains constant at the minimum baseline speed bmin. Because the gas discharge chamber 104 is young in age between times t1b and t2b, in this example, there is no requirement to increase the baseline speed in order to reduce or mitigate performance problems within the light source 100.

At time t2b, the apparatus 110 begins to increase or increment the baseline speed. The baseline speed of the blower 108 is incremented at a constant rate 429b (or slope) as the gas discharge chamber 104 becomes older and ages over time (and as pulses of the light beam 102 are generated by the gas discharge chamber 104). The baseline speed of the blower 108 is increased or incremented from the minimum baseline speed bmin to the maximum baseline speed bmax such that the baseline speed reaches the maximum baseline speed bmax at time t3b that is at the end of the lifetime of the gas discharge chamber 104.

The example of FIG. 4C is similar to the example of FIG. 4B, except the baseline speed of the blower 108 remains constant for a shorter amount of time dS and the baseline speed is incremented at a rate 429c that is slower than the rate 429b. After decrementing the baseline speed to the minimum baseline speed bmin at time t1c, and maintaining this minimum baseline speed bmin for a time dS, at time t2c, the baseline speed is increased at the constant rate 429c as the gas discharge chamber 104 becomes older and ages over time until the baseline speed of the blower 108 reaches the maximum baseline speed bmax at time t3c, which is at the end of the lifetime of the gas discharge chamber 104.

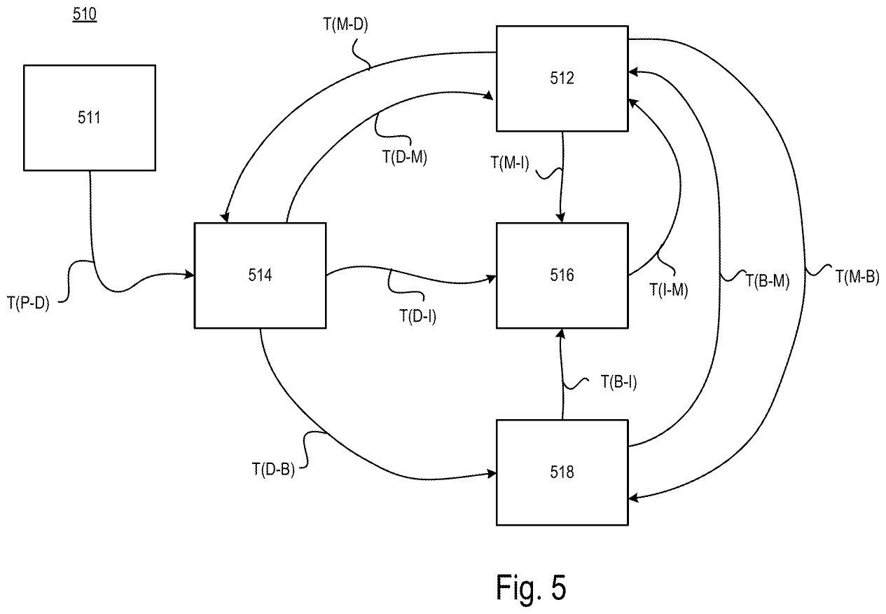

Referring to FIG. 5, the apparatus 110 (FIG. 2) is represented as a state machine 510 for the light source 100. In this representation of the state machine 510, the monitoring module 112 is represented by a monitoring state 512, the decrement module 114 is represented by a decrement state 514, and the increment module 116 is represented by an increment state 516. The state machine 510 can also include a baseline state 518, which represents the baseline module 118 (FIG. 2). Moreover, in this implementation, the state machine 510 includes a passive state 511 in which there are no commands or instructions from the state machine 510 to change or adjust the operating speed of the blower 108.

The state machine 510 transitions from the passive state 511 to the decrement state 514 T(P-D) if a number of pulses of the light beam 102 generated from the gas discharge chamber 104 is above a threshold value or after the state machine 510 has been in the passive state 511 for a threshold period of time. In general, the decrement state 514 is configured to reduce the operating speed of the blower 108 if the fault status 327 relating to one or more operating conditions of the light source 100 is clear and if the decreased operating speed would be at or above the baseline speed.

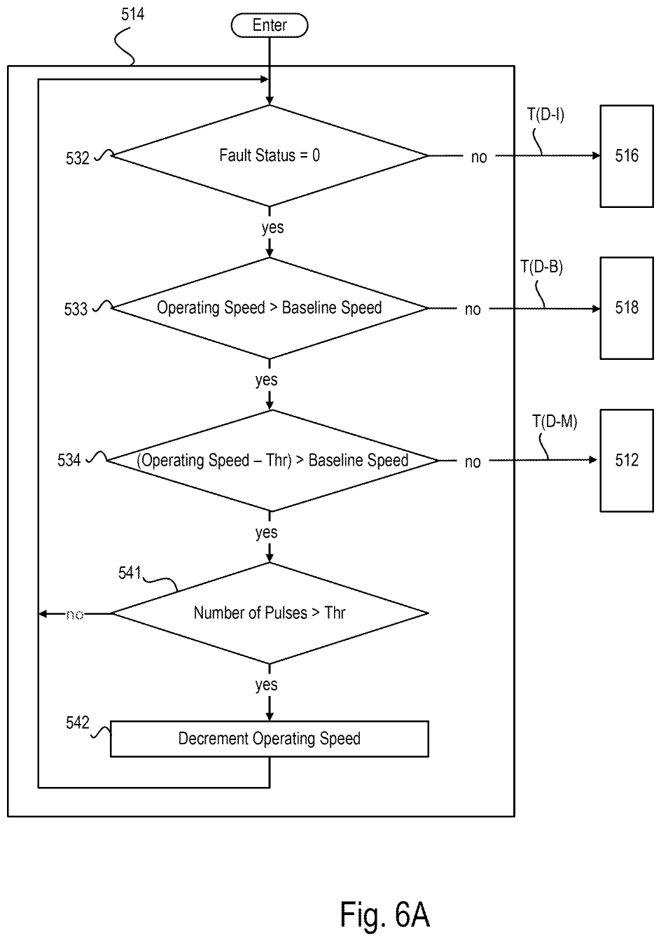

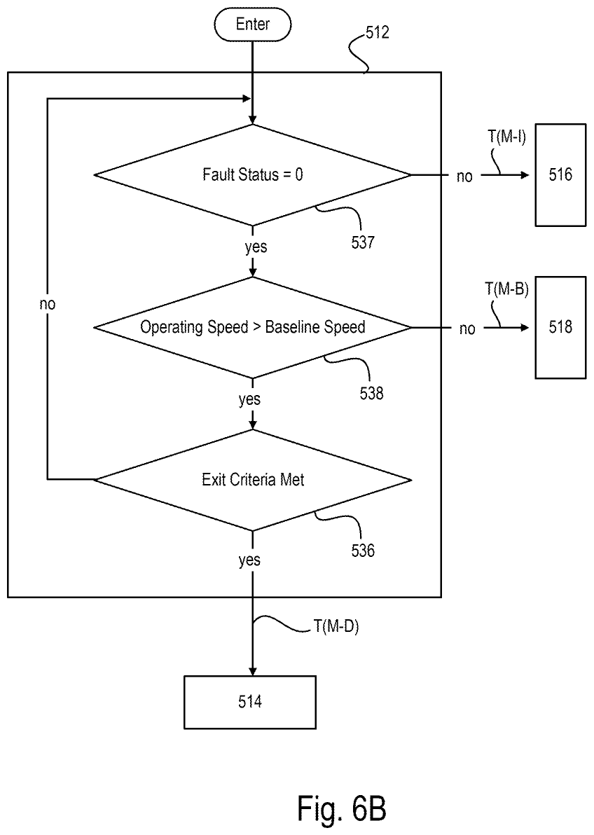

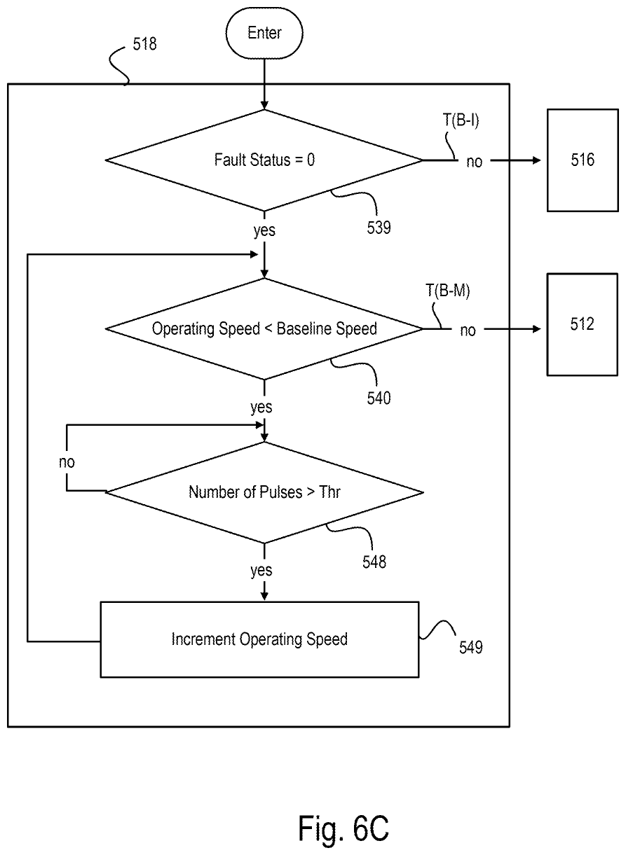

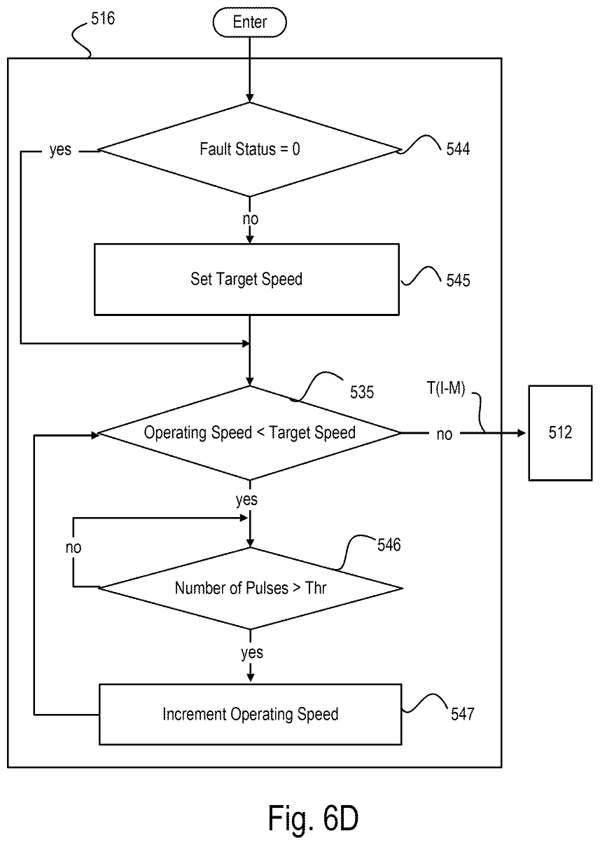

Specifically, and referring also to FIG. 6A, in the decrement state 514, the decrement module 114 determines if the fault status 327 of the light source 100 is clear (for example, at 0) (532). If the fault status 327 is not clear (and thus is flagged or has a value of 1) (532), then the decrement module 114 exits the decrement state 514 and the state machine 510 transitions from the decrement state 514 to the increment state 516 T(D-I) such that the operating speed of the blower 108 is incremented to a safe operating speed at which problems and/or failures do not occur within the light source 100.

If the fault status is clear (or has a value of 0) (532), then the decrement module 114 determines whether the operating speed of the blower 108 is greater than the baseline speed (533). If the operating speed of the blower 108 is not greater than the baseline speed (which means it is either at or less than or crosses below the baseline speed of the blower 108), then the decrement module 114 exits the decrement state 514 and the state machine 510 transitions from the decrement state 514 to the baseline state 518 T(D-B) such that the operating speed of the blower 108 is incremented to a safe operating speed that is above the baseline speed at which problems and/or failures do not occur within the light source 100.

If the operating speed of the blower 108 is greater than the baseline speed (533), then the decrement module 114 determines whether a proposed new blower speed would be greater than the baseline speed (534). The proposed new blower speed is the operating speed of the blower 108 minus a decrement speed step size. If the proposed new speed of the blower 108 would not be greater than the baseline speed (that is, the proposed new blower speed would be either at the baseline speed or less than the baseline speed) (534), then the decrement module 114 exits the decrement state 514 and the state machine 510 transitions from the decrement state 514 to the monitoring state 512 T(D-M) such that the one or more operating conditions of the light source 100 and the operating speed of the blower 108 can be monitored.

If, on the other hand, the proposed new blower speed would be greater than the baseline speed (534), then the decrement module 114 determines whether the number of pulses of the light beam 102 generated by the gas discharge chamber 104 since the last time the blower speed was changed is greater than a threshold number of pulses (541). The threshold number of pulses can be pre-set to be a positive integer in order to reduce the frequency with which the blower speed is changed. For example, the frequency with which the blower speed is changed can be set to ensure that the light generation apparatus 105 and also the performance metrics have enough time to adjust for the effects of the change in blower speed. Moreover, it is possible to operate in the decrement state 514 without performing this step 541.

If the number of pulses of the light beam 102 generated by the gas discharge chamber 104 is not greater than the threshold number of pulses (and thus, it is equal to or less than a threshold number of pulses) (541), then the decrement module 114 returns to step 532 and repeats steps 532, 533, 534. If the number of pulses of the light beam 102 generated by the gas discharge chamber 104 is greater than the threshold number of pulses (541), then the decrement module 114 instructs the blower 108 to decrease or decrement its operating speed (542). For example, the decrement state 514 can decrement the operating speed of the blower 108 by a decrement speed step size.

After decreasing the operating speed of the blower 108 in the decrement state 514 (542), decrement module 114 returns to querying whether the fault status 327 relating to the one or more operating conditions of the light source 100 is clear (for example, has a value of 0) (532).

Thus, in sum, the decrement module 114 causes the speed of the blower 108 to be reduced (524) if there is no fault (532), if the speed of the blower 108 is greater than the baseline speed (533), if the proposed new blower speed would be greater than the baseline speed (534), and if a certain number of pulses of the light beam 102 have been produced since the last change in the blower speed (541). In this way, the energy consumed by the blower 108 is significantly reduced, especially during the beginning of the lifetime of the light source 100 and the gas discharge chamber 104.

Referring also to FIG. 5, and as discussed above with reference to FIG. 6A, if the proposed new speed of the blower 108 would not be greater than the baseline speed (that is, the proposed new blower speed would be either at the baseline speed or less than the baseline speed) (534), then the decrement module 114 exits the decrement state 514 and the state machine 510 transitions from the decrement state 514 to the monitoring state 512 T(D-M) such that the one or more operating conditions of the light source 100 and the operating speed of the blower 108 can be monitored.

In general, in the monitoring state 512, the monitoring module 112 is configured to monitor exit criteria and remaining in the monitoring state 512 while there is no fault, the blower speed is greater than the baseline speed, and there is no occurrence of an exit criteria event. Referring to FIG. 6B, in the monitoring state 512, the monitoring module 112 determines whether the fault status 327 relating to the one or more operating conditions of the light source 100 is clear (for example, has a value of 0) (537). If the fault status 327 is not clear (and thus is flagged) (537), then the state machine 510 transitions from the monitoring state 512 to the increment state 516 T(M-I) such that the operating speed of the blower 108 is increased to a safe operating speed at which problems and/or failures do not occur within the light source 100.

If the fault status is clear (or has a value of 0) (537), then the monitoring module 112 determines whether the operating speed of the blower 108 is greater than the baseline speed (538). If the operating speed of the blower 108 is less than or below the baseline speed (538), then the state machine 510 transitions from the monitoring state 512 to the baseline state 518 T(M-B) such that the operating speed of the blower 108 is increased to a safe operating speed at which problems and/or failures do not occur within the light source 100. If the operating speed of the blower 108 is greater than the baseline speed (538), then the monitoring module 112 determines whether one or more exit criteria are met (536). For example, the exit criteria can be based on one or more of the baseline speed, a number of pulses of the light beam 102 produced by the light source 100, and events that lead to an improvement in performance of the light source 100. If the exit criteria are met, then the state machine 510 transitions from the monitoring state 512 to the decrement state 514 (because the light source 100 is determined to be in a safe condition to decrease the operating speed of the blower 108) T(M-D). If the exit criteria are not met, then the monitoring module 112 returns to determining whether the fault status 327 relating to the one or more operating conditions of the light source 100 is clear (for example, has a value of 0) (537). One possible exit criterion that can be evaluated at step 536 is a determination as to whether the speed of the blower 108 is greater than the baseline speed plus a lower threshold value (such as 200 rpm). In this case, then it seems more appropriate for the blower speed to be reduced (by way of the decrement state 514). Another possible exit criterion that can be evaluated at step 536 is to determine whether the current produced number of pulses of the light beam 102 is greater than a pre-determined threshold such as 100 million pulses. Alternatively, instead of evaluating a set of exit criteria at step 536 based on a number of produced pulses of the light beam 102, the monitoring module 112 can evaluate whether certain performance-improving events have occurred. For example, a performance-improving event could be a gas refill or injection in which the gas mixture 107 is at least partly or fully replaced. Such an event can lead to an improved performance of the light source 100.

Referring again to FIG. 5, and as discussed above with reference to FIG. 6A, if the operating speed of the blower 108 is at or less than the baseline speed (533), then the decrement module 114 exits the decrement state 514 and the state machine 510 transitions from the decrement state 514 to the baseline state 518 T(D-B) such that the operating speed of the blower 108 is incremented to a safe operating speed that is above the baseline speed at which problems and/or failures do not occur within the light source 100. The baseline state 518 is discussed with reference to FIG. 6C. Generally, the baseline state 518 is configured to increase the operating speed of the blower 108 if the operating speed of the blower 108 is at or below the baseline speed. The baseline module 118 determines if the fault status 327 of the light source 100 is clear (for example, equal to 0) (539). If the fault status 327 is not clear (and is therefore flagged or has a value of 1) (539), then the state machine 510 transitions from the baseline state 518 to the increment state 516 T(B-I) such that the operating speed of the blower 108 is incremented to a safe operating speed at which problems and/or failures do not occur within the light source 100.

If the fault status is clear (or has a value of 0) (539), then the baseline module 118 and determines whether the operating speed of the blower 108 is less than the baseline speed (540). If the operating speed is of the blower 108 is not less than the baseline speed (540), then the state machine 510 transitions from the baseline state 518 to the monitoring state 512 (since the operating speed is not required to be increased) T(B-M). If, on the other hand, the operating speed of the blower 108 is less than the baseline speed (540), then the baseline module 118 determines whether the number of pulses of the light beam 102 generated by the gas discharge chamber 104 since the last time the blower speed was changed is greater than a threshold number of pulses (548). As discussed above, the threshold number of pulses can be pre-set to be a positive integer in order to reduce the frequency with which the blower speed is changed. If the number of pulses of the light beam 102 generated by the gas discharge chamber 104 is not greater than a threshold number of pulses (548), then the baseline module 118 continues to query whether the number of pulses of the light beam 102 generated by the gas discharge chamber 104 since the last time the blower speed was changed in greater than a threshold number of pulses (548).

If the number of pulses of the light beam 102 generated by the gas discharge chamber 104 is greater than the threshold number of pulses (548), then the baseline module 118 increases or increments the operating speed of the blower 108 (549). For example, the baseline module 118 can increment the operating speed of the blower 108 by an increment speed step size. As an example, the increment speed step size can be about 5 rotations per minute (rpm). After increasing the operating speed of the blower 108, the baseline module 118 returns again to step 439 to determine if the fault status 327 of the light source 100 is clear (for example, equal to 0).

Referring again to FIG. 5, and as discussed above with reference to FIGS. 6A-6C, the state machine 510 can transition from any one of the decrement state 514, the monitoring state 512, and the baseline state 518 to the increment state 516. For example, while in the decrement state 514, if the fault status 327 is not clear (and thus is flagged or has a value of 1) (532), then the decrement module 114 exits the decrement state 514 and the state machine 510 transitions from the decrement state 514 to the increment state 516 T(D-I). In general, in the increment state 516, the operating speed of the blower 108 is incremented to a safe operating speed at which problems and/or failures do not occur within the light source 100. The increment state 516 is discussed next with reference to the implementation shown in FIG. 6D.

Specifically, in the increment state 516, the increment module 116 determines if the fault status 327 of the light source 100 is clear (for example, 0) (544). If the fault status 327 is not clear (for example, if the fault status is 1) (544), then the increment module 116 sets a new target speed for the blower 108 (545). The new target speed of the blower 108 can be equal to the operating speed of the blower 108 plus a large increment speed step size (such as, for example, 100 rpm). The idea is to significantly increase the speed of the blower 108 when a fault occurs. After the new target speed for the blower 108 is set (545) or after the increment module 116 determines that the fault status is clear (for example, the fault status is 0) (544), then the increment module 116 determines whether the operating speed of the blower 108 is less than the new target speed (535). If the operating speed of the blower 108 is not less than the new target speed (535), which means that the operating speed of the blower 108 is greater than or equal to the new target speed (535), then the state machine 510 transitions from the increment state 516 to the monitoring state 512 T(I-M).

If the operating speed of the blower 108 is less than the target speed (535), then the increment module 116 determines whether the number of pulses of the light beam 102 generated by the gas discharge chamber 104 is greater than a threshold number of pulses (546). If the number of pulses of the light beam 102 generated by the gas discharge chamber 104 is not greater than a threshold number of pulses, then the increment module 116 continues to query whether the number of pulses of the light beam 102 generated by the gas discharge chamber 104 is greater than a threshold number of pulses (546). If the number of pulses of the light beam 102 generated by the gas discharge chamber 104 is greater than the threshold number of pulses, then the increment module 116 increases or increments the operating speed of the blower 108 by a regular amount (547). For example, the increment module 116 can increment the operating speed of the blower 108 by an increment speed step size such as by 25 rpm. After increasing the operating speed of the blower 108 (547), the increment module 116 returns to step 535 to determine whether the increased operating speed of the blower 108 is less than the target speed (535).

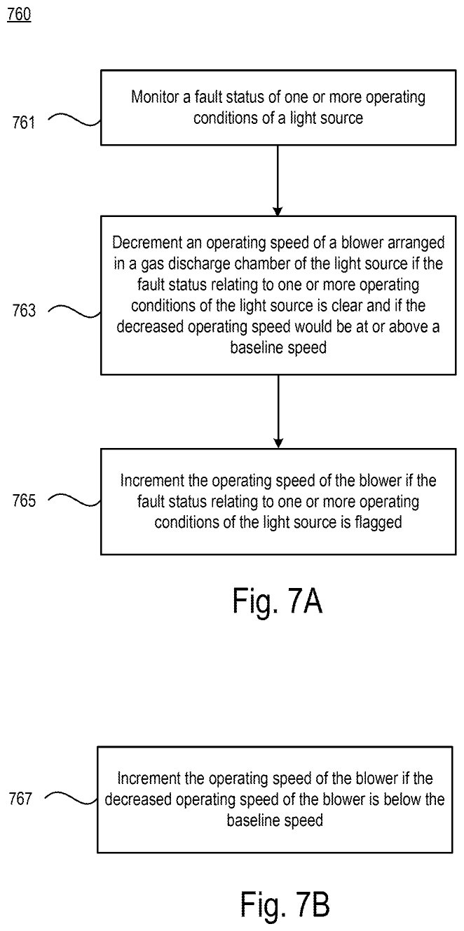

More generally, and while referring to FIG. 7A, the apparatus 110 performs a procedure 760 for controlling the blower 108. The procedure 760 can be performed with respect to the light source 100 (FIG. 1) that includes the apparatus 110 (FIG. 2) and the blower 108 in the gas discharge chamber 104. The procedure 760 can also be performed with respect to the state machine 510 (FIG. 5). In the following, the procedure 760 is described with respect to the light source 100 including the blower 108.

The procedure 760 includes monitoring a fault status of one or more operating conditions of the light source (761). For example, as discussed above with reference to FIG. 6B, the monitoring module 112 monitors the fault status 327 (FIG. 3) of the one or more operating conditions of the light source 100 (537).

Next, the apparatus 110 decrements the operating speed of the blower 108 if the fault status relating to one or more operating conditions of the light source 100 is clear and if the decreased operating speed would be at or above a baseline speed (763). For example, and with reference to FIG. 6A, if the fault status 327 relating to the one or more operating conditions of the light source 100 is clear (532) and if the decreased operating speed of the blower 108 would be above the baseline speed (534), then the decrement module 114 decrements the operating speed of the blower 108 (542). Decrementing the operating speed of the blower 108 can include reducing the operating speed of the blower 108 by a decrement speed step size. Moreover, decrementing the operating speed of the blower 108 can include reducing an amount of vibrations within the light source 100 caused by movement of the blower 108.

On the other hand, and again with reference to FIG. 7, the apparatus 110 increments the operating speed of the blower 108 if the fault status relating to one or more operating conditions of the light source is flagged (765). For example, with reference to FIG. 6D, if the fault status 327 of the light source 100 is flagged, then the increment module 116 increments the operating speed of the blower 108 (547). Incrementing the operating speed of the blower 108 can include increasing the operating speed of the blower 108 by an increment speed step size. In this way, the increment module 116 prevents the blower 108 from operating at an operating speed that can lead to problems and/or failures within the light source 100.

Referring also to FIG. 7B, the procedure 760 can further include incrementing the operating speed of the blower if the decreased operating speed of the blower is below the baseline speed (767). For example, and with reference to FIG. 6C, if the baseline module 118 determines that the decreased operating speed of the blower 108 (that is decreased by the decrement module 114) is below the baseline speed (540), then the baseline module 118 increases or increments the operating speed of the blower 108 (549). Thus, similar to the increment module 116, the baseline module 118 prevents the blower 108 from operating at an operating speed that can lead to problems and/or failures within the light source 100.

In one example, decrementing and incrementing the operating speed of the blower 108 can include adjusting the operating speed of the blower 108 within a blower speed range defined by a minimum blower speed and a maximum blower speed. In other words, the operating speed of the blower 108 is adjusted by the increment and decrement modules 114, 116 (and also the baseline module 118) between the minimum blower speed and the maximum blower speed. As described above, the blower speed range is a safe range within which the light source 100 does not have problems and/or failures, and properly operates. Thus, the apparatus 110 can control the operating speed of the blower 108 by adjusting the operating speed within the safe blower speed range such that minimal energy is consumed by the blower 108 and the energy consumed by the light source 100 is reduced.

In some implementations, the procedure 760 further includes determining the increment and decrement speed step sizes of the blower 108, each speed step size being dependent on the fault status 327 relating to the one or more operating conditions of the light source 100. Specifically, one or more studies of the light source 100 can be performed by, for example, a user to determine the largest increment and decrement speed step sizes that both maintain stability of the light source 100 and do not adversely affect performance of the light source 100 (and so that the fault status 327 of the light source 100 remains clear). Moreover, the procedure 760 can further include determining the blower speed range of the blower 108, the blower speed range being dependent on the fault status 327 of the one or more operating conditions of the light source 100. Similarly, one or more studies of the light source 100 can be performed by, for example, a user to determine the minimum blower speed and the maximum blower speed (and, therefore, the blower speed range) such that the performance of the light source 100 is not adversely affected when the blower 108 operates within the blower speed range (and so that the fault status 327 of the light source 100 remains clear).

Referring back to FIG. 3, in some implementations, at least one of the operating conditions (that is associated with a respective performance metric 320_1 to 320_N) of the light source 100 is proactive and at least one of the operating conditions is reactive. Specifically, for a proactive operating condition, the operating speed of the blower 108 is adjusted (for example, by the increment module 116 or the decrement module 114) prior to the value 323_1 to 323_N of the associated performance metric 320_1 to 320_N not being within the threshold range 324_1 to 324_N of the performance metric 320_1 to 320_N. For a reactive operating condition, the operating speed of the blower 108 is adjusted (for example, by the increment module 116 or the decrement module 114) after the value 323_1 to 323_N of the associated performance metric 320_1 to 320_N is not within the threshold range 324_1 to 324_N of the performance metric 320_1 to 320_N. Moreover, in some implementations, each proactive operating condition is associated with a limited threshold range that is tighter than the actual threshold range 3241 to 324_N of the performance metric 320_1 to 320_N, and the operating speed of the blower 108 is adjusted (for example, by the increment module 116 or the decrement module 114) prior to the value 323_1 to 323_N of the associated performance metric 320_1 to 320_N not being within the actual threshold range 324_1 to 324_N by determining the fault status 325_1 to 325_N of the proactive operating condition based on the limited threshold range.

Referring to FIG. 8, an implementation 800 of the light source 100 (FIG. 1) includes a light generation apparatus 805 including two gas discharge chambers 804A, 804B, the light generation apparatus 805 producing a pulsed output light beam 802 directed to a lithography exposure apparatus 801. The pulsed output light beam 802 has a wavelength in the ultraviolet range (for example, in the deep ultraviolet range) for use by the lithography exposure apparatus 801 for patterning a semiconductor substrate or wafer 870. In the example of FIG. 8, the gas discharge chamber 804A is a part of a master oscillator configured to produce a seed light beam 802s and the gas discharge chamber 804B is a part of a power amplifier configured to produce the output light beam 802 from the seed light beam 802s. Each of the discharge chambers 804A, 804B includes a respective blower 808A, 808B, each of the blowers 808A, 808B being configured to displace a respective gas mixture 807A, 807B including a gain medium from a respective energy source 806A, 806B within the respective gas discharge chamber 804A, 804B. In the example of FIG. 8, the apparatus 110 is configured to control operating speeds of the two blowers 808A, 808B. Specifically, the apparatus 110 controls the blowers 808A, 808B to consume a minimal amount of energy or power during operation of the light source 800, while ensuring that problems and/or failures within the light source 800 do not occur (or, are at least reduced). Other implementations of the light source 800 are possible.

Each discharge chamber 804A, 804B is configured to hold the respective gas mixture 807A, 807B in a respective interior cavity 873A, 873B. The gas mixture 807A, 807B used in the respective discharge chamber 804A, 804B can be a combination of suitable gases for producing the respective light beam 802s, 802 around the required wavelengths, bandwidth, and energy. For example, the gas mixture 807A, 807B can include argon fluoride (ArF), which emits light at a wavelength of about 193 nm. Each discharge chamber 804A, 804B is defined by respective chamber walls 803A_1, 803A_2, 803B_1, 803B_2 configured to hold the respective blowers 808A, 808B and, in this implementation, respective optical components 875A, 876A, 877A, 875B, 876B, 877B. Each discharge chamber 804A, 804B houses the respective energy source 806A, 806B configured to supply energy to the gas mixture 807A, 807B in each interior cavity 873A, 873B. For example, each energy source 806A, 806B can include a pair of electrodes that form a potential difference and, in operation, excite the gain medium of the gas mixture 807A, 807B.

Each discharge chamber 804A, 804B can include one or more optical components. For example, the discharge chamber 804A includes the optical components 875A, 876A associated with the interior cavity 873A of the discharge chamber 804A. The optical components 875A, 876A can include windows that allow a light beam to travel in to and out of the interior cavity 873A of the discharge chamber 804A. The optical component 875A can be a partially reflecting/partially transmitting optical coupler to enable the seed light beam 802s to exit the discharge chamber 804A. Moreover, the light source 800 can further include other optical components external to the discharge chamber 804A such as the optical component 877A corresponding to a spectral feature selection module that selects a wavelength and/or a bandwidth of the seed light beam 802s output from the discharge chamber 804A. For example, the spectral feature selection module 877A can include one or more of beam expansion prisms or beam splitters. In this example, the optical component 875A is held within the chamber wall 803A_1 and the optical component 876A is held within the chamber wall 803A_2.

The discharge chamber 804B includes the optical components 875B, 876B associated with the interior cavity 873B of the discharge chamber 804B. The optical components 875B, 876B can include windows that allow a light beam (such as the seed light beam 802s and light beam 802) to travel in to and out of the interior cavity 873B of the discharge chamber 804B. Moreover, the light source 800 can further include other optical components external to the discharge chamber 804B such as an optical component 877B corresponding to a beam reverser or turner configured to direct the light beam 802 back through the discharge chamber 804B. In the example of FIG. 8, the optical component 875B is held within the chamber wall 803B_1 and the optical component 876B is held within the chamber wall 803B_2.

During operational use of the light source 800, the apparatus 110 controls the respective operating speeds of the two blowers 808A, 808B. In some implementations, the control of the operating speed of the blower 808A can be independent of the control of the operating speed of the blower 808B. In some implementations, each blower 808A, 808B is independently controlled by a dedicated apparatus (810A, 810B). Moreover, the apparatus 810B can be designed differently from the apparatus 810A to account for differences between how the discharge chambers 804A, 804B affect parameters of the output light beams. Additionally, while control of the blowers 808A, 808B are not coupled in these implementations, their simultaneous control by way of the apparatus 810A, 810B could couple in performance differently than when controlling only one because each blower 808A, 808B drives vibrations in the frame of the chamber 804A, 804B in a different manner.

In other implementations, the control of the operating speed of the blower 808A and/or the blower 808B can rely on performance metrics associated with the light generation apparatus 805 and thus the control of the two blowers 808A, 808B can be coupled.

In some implementations, it is possible to have a single apparatus 110 configured to control the blower 810A of the first discharge chamber 804A but not using the apparatus 110 to control the blower 810B of the second discharge chamber 804B.

Specifically, in the example of FIG. 8, the apparatus 110 (FIG. 2) includes the monitoring module 112 that monitors the fault status of one or more operating conditions of the light source 800, the decrement module 114 that reduces the operating speed of the appropriate blower 808A, 808B if the fault status relating to one or more operating conditions of the light source 800 is clear and if the decreased operating speed of the respective blower 808A, 808B would be at or above a baseline speed, and the increment module 116 that increases the operating speed of the appropriate blower 808A, 808B if the fault status relating to one or more operating conditions of the light source 800 is flagged. In this way, the apparatus 110 controls the blowers 808A, 808B to consume a minimal amount of energy or power during operation of the light source 800, such that problems and/or failures within the light source 800 are reduced or mitigated based on the fault status of the light source 800 and the baseline speed of the blower 808A, 808B.

Referring to FIG. 9A, an implementation 900 of the light source 100 (FIG. 1) includes a light generation apparatus 905 including a plurality of optical oscillators 909-1 to 909-N that each include a respective gas discharge chamber 904-1 to 904-N, and produces a pulsed light beam 902 directed to a lithography exposure apparatus 901, and a control system 950. The light source 900 is configured to produce an output light beam 902 in the ultraviolet range for use by, for example, the lithography exposure apparatus 901 for patterning a semiconductor substrate or wafer 970. Specifically, the lithography exposure apparatus 901 exposes the wafer 970 with a shaped exposure beam 902′ that is formed by passing the light beam 902 (which is an exposure beam in this example) through a projection optical system 995. In the example of FIG. 9A, the light generation apparatus 905 includes N optical oscillators 909-1 to 909-N, and therefore, N gas discharge chambers 904-1 to 904-N, where N is an integer that is greater than one. Each of the gas discharge chambers 904-1 to 904-N is configured to emit a respective light beam 978-1 to 978-N toward a beam combiner 993. In the example shown, the control system 950 is connected to the light generation apparatus 905 and the lithography exposure apparatus 901. Other implementations of the light source 900 are possible.

Each of the gas discharge chambers 904-1 to 904-N includes a respective blower 908-1 to 908-N, each of the blowers 908-1 to 908-N being configured to displace a respective gas mixture 907-1 to 907-N including a gain medium from a respective energy source 906-1 to 906-N within the respective gas discharge chamber 904-1 to 904-N. In the example of FIG. 9A, the apparatus 110 (FIG. 2) is included as part of the control system 950 as a blower controller that controls the operating speed of each of the blowers 908-1 to 908-N. The apparatus 110 is configured to control operating speeds of the blowers 908-1 to 908-N. Specifically, the apparatus 110 controls each blower 908-1 to 908-N to consume a minimal amount of energy or power during operation of the light source 900, while ensuring that problems and/or failures within the light source 900 do not occur (or, are at least reduced).

The details of the optical oscillator 909-1 are discussed below. The other N−1 optical oscillators in the light generation apparatus 905 include the same or similar features.

The optical oscillator 909-1 includes the gas discharge chamber 904-1, which houses an energy source 906-1 that can include, for example, a cathode and an anode, and the blower 908-1. The discharge chamber 904-1 also contains a gas mixture 907-1 including a gain medium. A resonator is formed between a spectral feature selection module 977-1 on one side of the discharge chamber 904-1 and an output coupler 980-1 on a second side of the discharge chamber 904-1. The spectral feature selection module 977-1 can include a diffractive optic such as, for example, a grating and/or a prism, that finely tunes the spectral output of the discharge chamber 904-1. In some implementations, the spectral feature selection module 977-1 includes a plurality of diffractive optical elements. For example, the spectral feature selection module 977-1 can include four prisms, some of which are configured to control a center wavelength of the light beam 978-1 and others of which are configured to control a spectral bandwidth of the light beam 978-1.

In some implementations, the spectral feature selection module 977-1 can include or be in communication with a spectral feature control system that is configured to control, for example, various components within the spectral feature selection module 977-1. In these implementations, the decrement module 114 and the increment module 116 of the apparatus 110 (that is part of the control system 950 in this example) can each be configured to avoid interfering blower operating speeds at which the aliased frequency of the second harmonic of the blower 908-1 interferes with the spectral feature control system associated with the light source 900. For example, the interfering blower operating speeds can be dependent on a repetition rate at which the light source 900 produces light beams (including the light beam 902 or the exposure beam 902′ in this example).

The optical oscillator 909-1 also includes a line center analysis module 981-1 that receives an output light beam from the output coupler 980-1. The line center analysis module 981-1 is a measurement system that can be used to measure or monitor the wavelength of the light beam 978-1. The line center analysis module 981-1 can provide data to the control system 950, and the control system 950 can determine metrics related to the light beam 978-1 based on the data from the line center analysis module 981-1. For example, the control system 950 can determine a beam quality metric or a spectral bandwidth based on the data measured by the line center analysis module 981-1.

The light generation apparatus 905 also includes a gas supply system 990 that is fluidly coupled to an interior of the discharge chamber 904-1 via a fluid conduit 998. The fluid conduit 998 is any conduit that is capable of transporting a gas or other fluid with no or minimal loss of the fluid. For example, the fluid conduit 998 can be a pipe that is made of or coated with a material that does not react with the fluid or fluids transported in the conduit 998. The gas supply system 990 includes a chamber 991 that contains and/or is configured to receive a supply of the gas or gasses used in the gas mixture 907-1. The gas supply system 990 also includes devices (such as pumps, valves, and/or fluid switches) that enable the gas supply system 990 to remove gas from or inject gas into the discharge chamber 904-1. The gas supply system 990 is coupled to the control system 950. The gas supply system 990 can be controlled by the control system 950 to perform, for example, a refill procedure.

The other N−1 optical oscillators are similar to the optical oscillator 904-1 and have similar or the same components and subsystems. For example, each of the optical oscillators 909-1 to 909-N includes an energy source similar to the energy source 906-1, a spectral feature selection module similar to the spectral feature selection module 977-1, and an output coupler similar to the output coupler 980-1. The optical oscillators 909-1 to 909-N can be tuned or configured such that all of the light beams 978-1 to 978-N have the same properties or the optical oscillators 909-1 to 909-N can be tuned or configured such that at least some optical oscillators have at least some properties that are different from other optical oscillators. For example, all of the light beams 978-1 to 978-N can have the same center wavelength, or the center wavelength of each light beam 978-1 to 978-N can be different. The center wavelength produced by a particular one of the optical oscillators 909-1 to 909-N can be set using the respective spectral feature selection module.

The light generation apparatus 905 also includes a beam control apparatus 992 and the beam combiner 993. The beam control apparatus 992 is between the gas mixture of the optical oscillators 909-1 to 909-N and the beam combiner 993. The beam control apparatus 992 determines which of the light beams 978-1 to 978-N are incident on the beam combiner 993. The beam combiner 993 forms the exposure beam 902 from the light beam or light beams that are incident on the beam combiner 993. In the example shown, the beam control apparatus 992 is represented as a single element. However, the beam control apparatus 992 can be implemented as a collection of individual beam control apparatuses. For example, the beam control apparatus 992 can include a collection of shutters, with one shutter being associated with each optical oscillator 909-1 to 909-N.

The light generation apparatus 905 can include other components and systems. For example, the light generation apparatus 905 can include a beam preparation system 994 that includes a bandwidth analysis module that measures various properties (such as the bandwidth or the wavelength) of a light beam. The beam preparation system 994 also can include a pulse stretcher (not shown) that stretches each pulse that interacts with the pulse stretcher in time. The beam preparation system 994 also can include other components that are able to act upon light such as, for example, reflective and/or refractive optical elements (such as, for example, lenses and mirrors), and/or filters. In the example shown, the beam preparation system 994 is positioned in the path of the exposure beam 902. However, the beam preparation system 994 can be placed at other locations within the light source 900. Moreover, other implementations are possible. For example, the light generation apparatus 905 can include N instances of the beam preparation system 994, each of which is placed to interact with one of the light beams 978-1 to 978-N. In another example, the light generation apparatus 905 can include optical elements (such as mirrors) that steer the light beams 978-1 to 978-N toward the beam combiner 993.

The lithography exposure apparatus 901 can be a liquid immersion system or a dry system. The lithography exposure apparatus 901 includes a projection optical system 995 through which the exposure beam 902 passes prior to reaching the wafer 970, and a sensor system or metrology system 997. The wafer 970 is held or received on a wafer holder 996. Referring also to FIG. 9B, the projection optical system 995 includes a slit 995a, a mask 995b, and a projection objective, which includes a lens system 995c. The lens system 995c includes one or more optical elements. The exposure beam 902 enters the lithography exposure apparatus 901 and impinges on the slit 995a, and at least some of the beam 902 passes through the slit 995a to form the shaped exposure beam 902′. In the example of FIGS. 9A and 9B, the slit 995a is rectangular and shapes the exposure beam 902 into an elongated rectangular shaped light beam, which is the shaped exposure beam 902′. The mask 995b includes a pattern that determines which portions of the shaped light beam are transmitted by the mask 995b and which are blocked by the mask 995b. Microelectronic features are formed on the wafer 970 by exposing a layer of radiation-sensitive photoresist material on the wafer 970 with the exposure beam 902′. The design of the pattern on the mask is determined by the specific microelectronic circuit features that are desired.

The embodiments can be further described using the following clauses:
1. An apparatus for a light source, the apparatus comprising:
a monitoring module configured to monitor a fault status of one or more operating conditions of the light source;
a decrement module configured to reduce an operating speed of a blower arranged in a gas discharge chamber of the light source if the fault status relating to one or more operating conditions of the light source is clear and if the decreased operating speed would be at or above a baseline speed, the blower configured to displace a gas mixture including a gain medium from an energy source within the gas discharge chamber, the energy source configured to supply energy to the gas mixture; and
an increment module configured to increase the operating speed of the blower if the fault status relating to one or more operating conditions of the light source is flagged.
2. The apparatus of clause 1, wherein the baseline speed of the blower is related to an age of the gas discharge chamber, the baseline speed changing as the gas discharge chamber ages over time.
3. The apparatus of clause 1, wherein each of the one or more operating conditions is defined by a performance metric relating to the light source or to a light beam produced by the light source.
4. The apparatus of clause 3, wherein the one or more performance metrics include a wavelength histogram associated with the light beam, an energy dose error associated with the light beam, an energy error associated with the light beam, and an operating point of the gas discharge chamber within the light source.
5. The apparatus of clause 3, wherein the fault status is flagged if at least one of the associated performance metrics is not within a threshold range of that performance metric, and the fault status is clear if all of the associated performance metrics are within their respective threshold range.
6. The apparatus of clause 5, wherein at least one of the operating conditions of the light source is proactive such that the operating speed of the blower is adjusted prior to the value of the associated performance metric not being within the threshold range of the performance metric, and at least one of the operating conditions is reactive such that the operating speed of the blower is adjusted after the value of the associated performance metric is not within the threshold range of the performance metric.
7. The apparatus of clause 6, wherein each proactive operating condition is associated with a limited threshold range that is tighter than the actual threshold range of the performance metric, and the operating speed of the blower is adjusted prior to the value of the associated performance metric not being within the actual threshold range by determining the fault status of the proactive operating condition based on the limited threshold range.
8. The apparatus of clause 1, wherein the fault status relating to the one or more operating conditions of the light source is determined using a low pass filter or a weighted sum filter.
9. The apparatus of clause 1, wherein the decrement module is configured to reduce the operating speed of the blower by a decrement speed step size, and the increment module is configured to increase the operating speed of the blower by an increment speed step size.
10. The apparatus of clause 9, wherein the increment speed step size is larger than the decrement speed step size.
11. The apparatus of clause 9, wherein the increment speed step size is less than or equal to 25 rotations per minute (rpm), and the decrement speed step size is about one half, one third, one fourth, or one fifth of the increment speed step size.
12. The apparatus of clause 1, wherein the operating speed of the blower is adjusted by the increment and decrement modules within a blower speed range defined by a minimum blower speed and a maximum blower speed.
13. The apparatus of clause 1, wherein the decrement module and the increment module are each configured to avoid blower operating speeds at which the aliased frequency of the second harmonic of the blower interferes with a spectral feature control system associated with the light source.
14. The apparatus of clause 13, wherein the interfering blower operating speeds are dependent on a repetition rate at which the light source produces light beams.
15. The apparatus of clause 1, further comprising a baseline module configured to increase the operating speed of the blower if the operating speed of the blower is below the baseline speed.
16. The apparatus of clause 1, wherein:
the apparatus is a state machine for the light source such that the monitoring module is a monitoring state, the decrement module is a decrement state, and the increment module is an increment state.
17. The apparatus of clause 16, wherein, after decreasing the operating speed of the blower in the decrement state, the state machine transitions from the decrement state to the increment state if the fault status relating to one or more operating conditions of the light source is flagged.
18. The apparatus of clause 16, wherein the state machine further comprises a baseline state configured to increase the operating speed of the blower if the operating speed of the blower is below the baseline speed, and the state machine transitions from the decrement state to the baseline state if the operating speed of the blower crosses below the baseline speed.
19. The apparatus of clause 18, wherein, after the baseline state increases the operating speed of the blower in the baseline state, the state machine transitions from the baseline state to the increment state if the fault status relating to one or more operating conditions of the light source is flagged.
20. The apparatus of clause 18, wherein the state machine transitions from the monitoring state to the baseline state if the operating speed of the blower is below the baseline speed.
21. The apparatus of clause 16, wherein, after increasing the operating speed of the blower in the increment state, the state machine transitions from the increment state to the monitoring state if the increased operating speed of the blower is greater than a target speed.
22. The apparatus of clause 16, wherein the state machine transitions from the monitoring state to the increment state if the fault status relating to one or more operating conditions of the light source is flagged.
23. The apparatus of clause 16, wherein the state machine transitions from the monitoring state to the decrement state if one or more exit criteria are met, the exit criteria being based on one or more of the baseline speed, a number of light beam pulses produced by the light source, and events that lead to an improvement in performance of the light source.
24. A blower controller for a light source, the blower controller comprising:
a control system in communication with a blower arranged in a gas discharge chamber of the light source, the blower configured to displace a gas mixture including a gain medium from an energy source within the gas discharge chamber, the energy source configured to supply energy to the gas mixture, the control system configured to:
monitor a fault status of one or more operating conditions of the light source;
decrease an operating speed of the blower in a decrement state if the fault status relating to one or more operating conditions of the light source is clear and if the decreased operating speed would be at or above a baseline speed; and
increase the operating speed of the blower in an increment state if the fault status relating to one or more operating conditions of the light source is flagged.
25. The blower controller of clause 24, wherein the control system comprises:
a computer-readable memory module; and one or more electronic processors coupled to the computer-readable memory module.
26. The blower controller of clause 24, wherein the fault status relating to the one or more operating conditions is defined using binary notation, such that the fault status is assigned a value of zero if the fault status is clear and a value of one if the fault status is flagged.
27. The blower controller of clause 24, wherein the control system is further configured to increase the operating speed of the blower in the increment state if the decreased operating speed of the blower is below the baseline speed.
28. A method for controlling a blower arranged in a gas discharge chamber of a light source, the method comprising:
monitoring a fault status of one or more operating conditions of the light source;
decrementing an operating speed of the blower if the fault status relating to one or more operating conditions of the light source is clear and if the decreased operating speed would be at or above a baseline speed; and
incrementing the operating speed of the blower if the fault status relating to one or more operating conditions of the light source is flagged.
29. The method of clause 28, wherein decrementing the operating speed of the blower comprises reducing an amount of vibrations within the light source caused by movement of the blower.
30. The method of clause 28, wherein decrementing the operating speed of the blower comprises reducing the operating speed of the blower by a decrement speed step size, and incrementing the operating speed of the blower comprises increasing the operating speed of the blower by an increment speed step size.
31. The method of clause 30, further comprising determining the increment and decrement speed step sizes of the blower, each speed step size dependent on the fault status relating to the one or more operating conditions of the light source.
32. The method of clause 28, wherein decrementing and incrementing the operating speed of the blower comprises adjusting the operating speed of the blower within a blower speed range defined by a minimum blower speed and a maximum blower speed.
33. The method of clause 32, further comprising determining the blower speed range of the blower, the blower speed range dependent on the fault status of the one or more operating conditions of the light source.
34. The method of clause 28, further comprising incrementing the operating speed of the blower if the decreased operating speed of the blower is below the baseline speed.
35. The method of clause 28, wherein monitoring the fault status relating to the one or more operating conditions comprises monitoring one or more exit criteria such that the operating speed of the blower is decreased only if one or more of the exit criteria are met.
36. The method of clause 35, wherein the exit criteria are based on the baseline speed and a number of light beam pulses produced by the light source, the exit criteria being met if the operating speed of the blower is greater than the baseline speed and the number of light beam pulses is greater than a minimum number of pulses.
37. An ultraviolet light source comprising:
a light generation apparatus comprising one or more gas discharge chambers configured to hold a gas mixture including a gain medium, to house an energy source configured to supply energy to the gas mixture, and to produce a light beam, at least one of the gas discharge chambers being configured to hold a blower configured to displace the gas mixture from the energy source within the gas discharge chamber; and
an apparatus configured to adjust an operating speed of the blower, the apparatus comprising: a monitoring module configured to monitor a fault status relating to one or more operating conditions of the light source;
a decrement module configured to decrease the operating speed of the blower if the fault status relating to one or more operating conditions of the light source is clear and if the decreased operating speed would be at or above a baseline speed; and
an increment module configured to increase the operating speed of the blower if the fault status of one or more operating conditions of the light source is flagged.
38. The ultraviolet light source of clause 37, wherein the gain medium is configured to emit deep ultraviolet (DUV) light in response to a voltage signal being applied to the energy source.
39. The ultraviolet light source of clause 38, wherein the gaseous gain medium comprises argon fluoride (ArF), krypton fluoride (KrF), or xenon chloride (XeCl).
40. The ultraviolet light source of clause 37, wherein the light generation apparatus comprises two gas discharge chambers including a master oscillator configured to produce a seed light beam and a power amplifier configured to produce an output light beam from the seed light beam.
41. The ultraviolet light source of clause 37, wherein the light generation apparatus comprises a plurality of gas discharge chambers, and each of the gas discharge chambers is configured to emit a light beam toward a beam combiner.
42. The ultraviolet light source of clause 37, wherein the apparatus comprises a baseline module configured to increase the operating speed of the blower if the decreased operating speed of the blower is below the baseline speed.

Other implementations are within the scope of the claims.

1. An apparatus for a light source, the apparatus comprising:
a monitoring module configured to monitor a fault status of one or more operating conditions of the light source;
a decrement module configured to reduce an operating speed of a blower arranged in a gas discharge chamber of the light source if the fault status relating to one or more operating conditions of the light source is clear and if the decreased operating speed would be at or above a baseline speed, the blower configured to displace a gas mixture including a gain medium from an energy source within the gas discharge chamber, the energy source configured to supply energy to the gas mixture; and
an increment module configured to increase the operating speed of the blower if the fault status relating to one or more operating conditions of the light source is flagged.

2. (canceled)

3. The apparatus of claim 1, wherein each of the one or more operating conditions is defined by a performance metric relating to the light source or to a light beam produced by the light source.

4. The apparatus of claim 3, wherein the one or more performance metrics include a wavelength histogram associated with the light beam, an energy dose error associated with the light beam, an energy error associated with the light beam, and an operating point of the gas discharge chamber within the light source.

5-7. (canceled)

8. The apparatus of claim 1, wherein the fault status relating to the one or more operating conditions of the light source is determined using a low pass filter or a weighted sum filter.

9. The apparatus of claim 1, wherein the decrement module is configured to reduce the operating speed of the blower by a decrement speed step size, and the increment module is configured to increase the operating speed of the blower by an increment speed step size.

10. The apparatus of claim 9, wherein the increment speed step size is larger than the decrement speed step size.

11. (canceled)

12. (canceled)

13. The apparatus of claim 1, wherein the decrement module and the increment module are each configured to avoid blower operating speeds at which the aliased frequency of the second harmonic of the blower interferes with a spectral feature control system associated with the light source.

14. The apparatus of claim 13, wherein the interfering blower operating speeds are dependent on a repetition rate at which the light source produces light beams.

15. The apparatus of claim 1, further comprising a baseline module configured to increase the operating speed of the blower if the operating speed of the blower is below the baseline speed.

16. (canceled)

17. The apparatus of claim 1, wherein the apparatus is a state machine for the light source such that the monitoring module is a monitoring state, the decrement module is a decrement state, and the increment module is an increment state and, after decreasing the operating speed of the blower in the decrement state, the state machine transitions from the decrement state to the increment state if the fault status relating to one or more operating conditions of the light source is flagged.

18. The apparatus of claim 1, wherein the apparatus is a state machine for the light source such that the monitoring module is a monitoring state, the decrement module is a decrement state, and the increment module is an increment state and the state machine further comprises a baseline state configured to increase the operating speed of the blower if the operating speed of the blower is below the baseline speed, and the state machine transitions from the decrement state to the baseline state if the operating speed of the blower crosses below the baseline speed.

19. (canceled)

20. The apparatus of claim 18, wherein the state machine transitions from the monitoring state to the baseline state if the operating speed of the blower is below the baseline speed.

21. (canceled)

22. (canceled)

23. The apparatus of claim 1, wherein the apparatus is a state machine for the light source such that the monitoring module is a monitoring state, the decrement module is a decrement state, and the increment module is an increment state and the state machine transitions from the monitoring state to the decrement state if one or more exit criteria are met, the exit criteria being based on one or more of the baseline speed, a number of light beam pulses produced by the light source, and events that lead to an improvement in performance of the light source.

24. A blower controller for a light source, the blower controller comprising:
a control system in communication with a blower arranged in a gas discharge chamber of the light source, the blower configured to displace a gas mixture including a gain medium from an energy source within the gas discharge chamber, the energy source configured to supply energy to the gas mixture, the control system configured to:
monitor a fault status of one or more operating conditions of the light source;
decrease an operating speed of the blower in a decrement state if the fault status relating to one or more operating conditions of the light source is clear and if the decreased operating speed would be at or above a baseline speed; and
increase the operating speed of the blower in an increment state if the fault status relating to one or more operating conditions of the light source is flagged.

25. (canceled)

26. The blower controller of claim 24, wherein the fault status relating to the one or more operating conditions is defined using binary notation, such that the fault status is assigned a value of zero if the fault status is clear and a value of one if the fault status is flagged.

27. The blower controller of claim 24, wherein the control system is further configured to increase the operating speed of the blower in the increment state if the decreased operating speed of the blower is below the baseline speed.

28-36. (canceled)

37. An ultraviolet light source comprising:
a light generation apparatus comprising one or more gas discharge chambers configured to hold a gas mixture including a gain medium, to house an energy source configured to supply energy to the gas mixture, and to produce a light beam, at least one of the gas discharge chambers being configured to hold a blower configured to displace the gas mixture from the energy source within the gas discharge chamber; and
an apparatus configured to adjust an operating speed of the blower, the apparatus comprising:
a monitoring module configured to monitor a fault status relating to one or more operating conditions of the light source;
a decrement module configured to decrease the operating speed of the blower if the fault status relating to one or more operating conditions of the light source is clear and if the decreased operating speed would be at or above a baseline speed; and
an increment module configured to increase the operating speed of the blower if the fault status of one or more operating conditions of the light source is flagged.

38-40. (canceled)

41. The ultraviolet light source of claim 37, wherein the light generation apparatus comprises a plurality of gas discharge chambers, and each of the gas discharge chambers is configured to emit a light beam toward a beam combiner.

42. The ultraviolet light source of claim 37, wherein the apparatus comprises a baseline module configured to increase the operating speed of the blower if the decreased operating speed of the blower is below the baseline speed.

43. An apparatus for controlling an operating speed of each blower in a plurality of blowers, each blower being arranged in a gas discharge chamber of a light generation apparatus of a light source, the apparatus comprising:
a monitoring module configured to monitor a fault status of one or more operating conditions of the light source;
a decrement module configured to reduce an operating speed of an appropriate blower if the fault status relating to one or more operating conditions of the light source is clear; and
an increment module configured to increase an operating speed of an appropriate blower if the fault status relating to one or more operating conditions of the light source is flagged.

44. The apparatus of claim 43, wherein the control of the speed of at least one of the blowers relies on performance metrics that define the operating conditions of the light generation apparatus such that control of the at least one blower and another blower is coupled.

45. The apparatus of claim 43, wherein the decrement module is configured to reduce the operating speed of the appropriate blower if a decreased operating speed of the blower would be at or above a baseline speed.

46. The apparatus of claim 43, wherein each of the one or more operating conditions is defined by a performance metric relating to the light source or to a light beam produced by the light source.

47. The apparatus of claim 46, wherein the one or more performance metrics include a wavelength histogram associated with the light beam, an energy dose error associated with the light beam, an energy error associated with the light beam, and an operating point of the gas discharge chamber within the light source.

48. The apparatus of claim 46, wherein the fault status is flagged if at least one of the associated performance metrics is not within a threshold range of that performance metric, and the fault status is clear if all of the associated performance metrics are within their respective threshold range.

49. The apparatus of claim 48, wherein at least one of the operating conditions of the light source is proactive such that the operating speed of the blower is adjusted prior to the value of the associated performance metric not being within the threshold range of the performance metric, and at least one of the operating conditions is reactive such that the operating speed of the blower is adjusted after the value of the associated performance metric is not within the threshold range of the performance metric.

50. The apparatus of claim 43, wherein the decrement module is configured to reduce the operating speed of the blower by a decrement speed step size, and the increment module is configured to increase the operating speed of the blower by an increment speed step size.

51. The apparatus of claim 50, wherein the increment speed step size is larger than the decrement speed step size.

52. The apparatus of claim 50, wherein the increment speed step size is less than or equal to 25 rotations per minute (rpm), and the decrement speed step size is about one half, one third, one fourth, or one fifth of the increment speed step size.

53. The apparatus of claim 43, wherein the operating speed of the blower is adjusted by the increment and decrement modules within a blower speed range defined by a minimum blower speed and a maximum blower speed.

54. The apparatus of claim 43, further comprising a baseline module configured to increase the operating speed of the blower if the operating speed of the blower is below the baseline speed.

55. The apparatus of claim 43, wherein:
the apparatus is a state machine for the light source such that the monitoring module is a monitoring state, the decrement module is a decrement state, and the increment module is an increment state.

56. The apparatus of claim 55, wherein, after decreasing the operating speed of the blower in the decrement state, the state machine transitions from the decrement state to the increment state if the fault status relating to one or more operating conditions of the light source is flagged.

57. An apparatus for a light source including a plurality of gas discharge chambers with a blower being arranged in each gas discharge chamber, the apparatus comprising:
a plurality of sub-apparatuses, each sub-apparatus dedicated to controlling a speed of an associated blower in one of the gas discharge chambers, and each sub-apparatus comprising:
a monitoring module configured to monitor a fault status of one or more operating conditions of the light source;
a decrement module configured to reduce an operating speed of the associated blower if the fault status relating to one or more operating conditions of the light source is clear; and
an increment module configured to increase an operating speed of the associated blower if the fault status relating to one or more operating conditions of the light source is flagged.

58. A blower controller for a light source including a plurality of gas discharge chambers with a blower being arranged in each gas discharge chamber, the blower controller comprising:
a plurality of apparatuses, each apparatus dedicated to independently control a speed of an associated blower in one of the gas discharge chambers, and each apparatus configured to:
monitor a fault status of one or more operating conditions of the light source;
reduce an operating speed of the associated blower if the fault status relating to one or more operating conditions of the light source is clear; and
increase an operating speed of the associated blower if the fault status relating to one or more operating conditions of the light source is flagged.

59. An ultraviolet light source comprising:
a light generation apparatus comprising a plurality of gas discharge chambers, each gas discharge chamber configured to hold a gas mixture including a gain medium, to house an energy source configured to supply energy to the gas mixture, and to produce a light beam, each gas discharge chamber being configured to hold a blower configured to displace the gas mixture from the energy source within the gas discharge chamber; and
an apparatus configured to control the operating speed of each blower, the apparatus comprising:
a monitoring module configured to monitor a fault status of one or more operating conditions of the light source;
a decrement module configured to reduce an operating speed of an appropriate blower if the fault status relating to one or more operating conditions of the light source is clear; and
an increment module configured to increase an operating speed of an appropriate blower if the fault status relating to one or more operating conditions of the light source is flagged.
